(19) United States
(12) Patent Application Publication
(10) Pub. No.: US 2025/0098198 A1
(43) Pub. Date: Mar. 20, 2025

(54) NANOSHEET DEVICE WITH ALIGNED ISOLATION AND EPITAXIAL GROWTH

(71) Applicant: International Business Machines Corporation, Armonk, NY (US)

(72) Inventors: Julien Frougier, Albany, NY (US); Ruilong Xie, Niskayuna, NY (US); Susan Ng Emans, Albany, NY (US); Chanro Park, Clifton Park, NY (US); Min Gyu Sung, Latham, NY (US); Juntao Li, Cohoes, NY (US); Tao Li, Slingerlands, NY (US)

(21) Appl. No.: 18/468,977

(22) Filed: Sep. 18, 2023

(51) Int. Cl. H01L 29/775; H01L 29/06; H01L 29/08; H01L 29/423; H01L 29/66

(52) U.S. Cl. CPC H10D 30/43; H10D 30/014; H10D 30/6735; H10D 62/121; H10D 62/151; H10D 64/017

(57) ABSTRACT

A semiconductor device that includes a stack of nanostructure material layers overlying a substrate, wherein a gate all around structure is present on a channel region portion for the stack of nanostructure material layers, and source and drain semiconductor contacts on each side of the gate all around structure. The source and drain semiconductor contacts are in direct contact with edges of the channel region portion for the stack of nanostructure material layers. A gate spacer between the source and drain semiconductor contacts and the gate all around structure. An electrically insulating substrate isolation layer aligned to be between the gate all around structure, the gate spacer and the substrate. A base portion of the gate spacer has an L-shaped geometry including a portion that warps over an upper surface of the electrically insulating substrate isolation layer.

### BACKGROUND

The present disclosure relates to semiconductor devices, and more particularly to semiconductor devices including channel regions integrated within nanosheets and epitaxially grown materials.

Modern integrated circuits are made up of literally millions of active devices such as transistors. Field effect transistors are widely used in the electronics industry for switching, amplification, filtering and other tasks related to both analog and digital electrical signals. Most common among these are metal oxide semiconductor field effect transistors (MOSFET or MOS), in which a gate structure is energized to create an electric field in an underlying channel region of a semiconductor body, by which electrons are allowed to travel through the channel between a source region and a drain region of the semiconductor body.

Nanosheet devices provide for increased device integration and improved scaling. However, due to the narrow dimension of the source and drain region sheets, source and drain epitaxial growth for the formation of source and drain contacts can be challenging. Additionally, punch through stop (PTS) implants into the substrate underlying the nanosheets can result in a parasitic channel.

### SUMMARY

The apparatus, structures and methods of the present disclosure can overcome the aforementioned difficulties. More specifically, isolation between the suspended nanosheets and the substrate can be provided by a self-aligned substrate isolation layer (also referred to as electrically insulating substrate isolation layer that is aligned to the gate structure) that is positioned between the lowest nanosheet in the channel stack and the substrate. The source and drain semiconductor contacts (e.g., source and drain contacts composed of epitaxially formed semiconductor materials) can be formed using unconfined, partially confined and fully confined epitaxial growth through the use of composite spacers. The details of the apparatus, structures and methods for providing a gate all around nanosheet device with self-aligned substrate isolation (SASI) and improved source and drain epitaxy are described herein.

In one aspect, a semiconductor device is provided that includes a stack of nanostructure material layers overlying a substrate, wherein a gate all around structure is present on a channel region portion for the stack of nanostructure material layers, and source and drain semiconductor contacts are present on each side of the gate all around structure. The source and drain semiconductor contacts are in direct contact with edges of the channel region portion for the stack of nanostructure material layers. A gate spacer is present between the source and drain semiconductor contacts and the gate all around structure. An electrically insulating substrate isolation layer is aligned to be between the gate all around structure, the gate spacer and the substrate. A base portion of the gate spacer has an L-shaped geometry including a portion that warps over an upper surface of the electrically insulating substrate isolation layer.

In some embodiments, the electrically insulating isolation layer is a self-aligned substrate isolation (SASI) layer that provides for isolation of the bottom channel regions in the nanosheet stack. This avoids the need for punch through stopper implants that can result in the formation of a parasitic channel.

In some embodiments, the gate spacer is a composite structure including an inner spacer and an outer spacer of different material compositions, wherein a first material provides the outer spacer including that at least the base portion of the gate spacer having the L-shaped geometry, and a second material provides the inner spacer. The second material that provides the inner spacer also provides a material composition for the electrically insulating substrate isolation layer. This is one example of source and drain contacts that are formed using an unconstrained epitaxial growth method. More particularly, in this embodiment, the source and drain semiconductor contacts are not confined by dielectric sidewalls.

In another embodiment, the source and drain semiconductor contacts are partially confined by a spacer material in direct contact between two adjacent source and drain semiconductor contacts along a single sidewall. In this embodiment, the gate spacer can include an upper portion atop the stack of nanostructure material layers that includes two different materials. For example, a first material provides an outer spacer having a same composition the base portion of the gate spacer having the L-shaped geometry, and a second material provides an inner spacer and has a same composition as the electrically insulating substrate isolation layer. In one example, the gate spacer includes an upper portion atop the stack of nanostructure material layers having a single composition that is composed of a dielectric material having a same composition as the electrically insulating substrate isolation layer. In one embodiment, the source and drain semiconductor contacts are only partially confined by dielectric sidewalls, which aids in epitaxial growth.

In another aspect of the present disclosure, a device is provided using a fully constrained version of epitaxial growth. In one embodiment, the semiconductor device includes a stack of nanostructure material layers overlying a substrate, in which a gate all around structure is present on a channel region portion for the stack of nanostructure material layers. In some embodiments, source and drain semiconductor contacts are present on each side of the gate all around structure. The source and drain semiconductor contacts are in direct contact with edges of the channel region portion for the stack of nanostructure material layers. The semiconductor device may include a composite gate spacer on the gate all around structure, wherein the composite gate spacer including a confining portion on sidewalls of the source and drain contacts. The semiconductor device may also include an electrically insulating substrate isolation layer that is aligned to be between the gate all around structure, the composite gate spacer and the substrate. In this example, a base portion of the composite gate spacer has an L-shaped geometry includes a portion that warps over an upper surface of the electrically insulating substrate isolation layer.

In some embodiments, the electrically insulating isolation layer is a self-aligned substrate isolation (SASI) layer. This avoids the need for punch through stopper implants that can result in the formation of a parasitic channel.

In some embodiments, the confining portion of the spacer on the sidewalls of the source and drain semiconductor contacts retains the epitaxial growth of the semiconductor material that provides the source and drain semiconductor contacts to produce sidewalls for the source and drain semiconductor contacts that are planar. In one example, the composite gate spacer includes an inner gate spacer, a nanosheet stack spacer, and outer gate spacer. A first material provides the nanosheet stack spacer including at least the base portion of the gate spacer having the L-shaped geometry, a second material provides the inner gate spacer, and a third material provides the outer gate spacer. In one example, the source and drain semiconductor contacts are composed of epitaxial semiconductor material that is partially confined by the spacer material that is in direct contact and between two adjacent source and drain semiconductor contacts along a single sidewall.

In yet another aspect of the present disclosure, a device is provided that includes an electrically insulating substrate isolation layer that has different thicknesses across the substrate. In one embodiment, the semiconductor device can include a stack of nanostructure material layers overlying a substrate. A gate all around structure can be present on a channel region portion for the stack of nanostructure material layers. Source and drain semiconductor contacts can be present on each side of the gate all around structure. The source and drain semiconductor contacts are in direct contact with edges of the channel region portion for the stack of nanostructure material layers. In some embodiments, a gate spacer is present on the gate all around structure, wherein the gate spacer includes a confining portion on sidewalls of the source and drain semiconductor contacts. In some embodiments, the device includes an electrically insulating substrate isolation layer having a first thickness aligned to be between the gate all around structure, the gate spacer and the substrate. The electrically insulating substrate isolation layer also has a second thickness present between the source and drain semiconductor contacts and the substrate. In some embodiments, a base portion of the gate spacer has an L-shaped geometry including a portion that warps over an upper surface of a portion of the electrically insulating substrate isolation layer having the first thickness. In some embodiments, the first thickness of the electrically insulating substrate isolation layer is greater than the second thickness. In some embodiments, this avoids the need for punch through stopper implants that can result in the formation of a parasitic channel.

In some embodiments, the gate spacer is a composite gate spacer including a confining portion on sidewalls of the source and drain semiconductor contacts. The composite gate spacer can include confining portions on sidewalls of the source and drain semiconductor contacts to limit epitaxial growth of the source and drain contacts. This can provide sidewalls for the source and drain semiconductor contacts that are planar. The composite gate spacer may include an inner gate spacer, a nanosheet stack spacer, and outer gate spacer. In one example, a first material provides the nanosheet stack spacer including that at least the base portion of the gate spacer having the L-shaped geometry, a second material provides the inner gate spacer and a third material provides the outer gate spacer. In one embodiment, the second material that provides the inner gate spacer provides a material composition for the electrically insulating substrate isolation layer. In some examples, an air gap is present between the source and drain contacts and a portion of the electrically insulating substrate isolation layer having the second thickness.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a side cross-sectional view of a semiconductor device along a gate length direction for a device that includes a gate all around nanosheet channel region with a self-aligned substrate isolation layer and sites for improved source-drain epitaxial nucleation, in accordance with one embodiment of the present disclosure.

FIG. 2 is a side cross-sectional view of a semiconductor device along a gate width direction for the structure depicted in FIG. 1

FIG. 3 is a top down view illustrating the relationship between the side cross-sectional views illustrated in FIGS. 1 and 2, in which the cross-section line identified by X-X is the line from which the cross section illustrated in FIG. 1 is taken, and the cross-section line identified by Y-Y is the line from which the cross section illustrated in FIG. 2 is taken.

FIG. 4 is a side cross-sectional view of a semiconductor device along a gate length direction for a device that includes a gate all around nanosheet channel region with a self-aligned substrate isolation layer and sites for improved source-drain epitaxial nucleation using partial confinement spacers, in accordance with one embodiment of the present disclosure.

FIG. 5 is a side cross-sectional view of a semiconductor device along a gate width direction for the structure depicted in FIG. 4.

FIG. 6 is a side cross-sectional view of a semiconductor device along a gate length direction for a device that includes a gate all around nanosheet channel region with a self-aligned substrate isolation layer and sites for improved source-drain epitaxial nucleation using full confinement spacers, in accordance with one embodiment of the present disclosure.

FIG. 7 is a side cross-sectional view of a semiconductor device along a gate width direction for the structure depicted in FIG. 6.

FIG. 8 is a side cross-sectional view of a semiconductor device along a gate length direction for a device that includes a gate all around nanosheet channel region with a substrate isolation layer having different thicknesses and sites for improved source-drain epitaxial nucleation using full confinement spacers, in accordance with one embodiment of the present disclosure.

FIG. 9 is a side cross-sectional view of a semiconductor device along a gate width direction for the structure depicted in FIG. 8.

FIG. 10 is a side cross-sectional view of an initial structure that may be employed in method that provides gate all around nanosheet devices with a self-aligned substrate isolation layer and improved source drain epitaxy nucleation, in accordance with one embodiment of the present disclosure.

FIG. 11 is a side cross-sectional view of a structure for a semiconductor device method along a gate width direction for the structure depicted in FIG. 10.

FIG. 12 a side cross-sectional view illustrating removing the first sacrificial nanosheet and replacing it with a dielectric material to provide the electrically insulating substrate isolation layer, in accordance with one embodiment of the present disclosure.

FIG. 13 is a side cross-sectional view of a semiconductor device along a gate width direction for the structure depicted in FIG. 12.

FIG. 14 is a side cross-sectional view of an anisotropic fin recess, and an isotropic etch back of the gate spacer material provided by the inner gate spacer, in accordance with one embodiment of the present disclosure.

FIG. 15 is a side cross-sectional view of a structure for a semiconductor device method along a gate width direction for the structure depicted in FIG. 14.

FIG. 16 is a side cross-sectional view of deposition of a dielectric material for forming the outer spacer, in accordance with one embodiment of the present disclosure.

FIG. 17 is a side cross-sectional view of a structure for a semiconductor device method along a gate width direction for the structure depicted in FIG. 17.

FIG. 18 is a side cross-sectional view illustrating a selective isotropic etch back of the dielectric material for the outer spacer and forming the source and drain semiconductor contacts, in accordance with one embodiment of the present disclosure.

FIG. 19 is a side cross-sectional view of a structure for a semiconductor device method along a gate width direction for the structure depicted in FIG. 18.

FIG. 20 is a side cross-sectional view of a process step for a method for forming a semiconductor device that includes the electrically insulating substrate isolation layer, in which the epitaxial material for the source and drain semiconductor contacts is formed using a partially confined method, wherein the process step depicted in FIG. 20 includes forming a dielectric material for an outer spacer.

FIG. 21 is a side cross-sectional view of a structure for a semiconductor device method along a gate width direction for the structure depicted in FIG. 20.

FIG. 22 is a side cross-sectional view of removing the protective spacer liner from the structure depicted in FIG. 20.

FIG. 23 is a side cross-sectional view of a structure for a semiconductor device method along a gate width direction for the structure depicted in FIG. 22.

FIG. 24 is a side cross-sectional view of a process step for a method for forming a semiconductor device that includes an electrically insulating substrate isolation layer, in which the epitaxial material for the source and drain semiconductor contacts is formed using a fully confined method.

FIG. 25 is a side cross-sectional view of a structure for a semiconductor device method along a gate width direction for the structure depicted in FIG. 24.

FIG. 26 is a side cross-sectional view of a process step for a method for forming a semiconductor device that includes an electrically insulating substrate isolation layer having at least two different thicknesses, in which the epitaxial material for the source and drain semiconductor contacts is formed using a fully confined method.

FIG. 27 is a side cross-sectional view of a structure for a semiconductor device method along a gate width direction for the structure depicted in FIG. 26.

FIG. 28 is a side cross-sectional view that illustrates a selective etch process applied to the structure depicted in FIG. 26 that results in a partial etch back of the gate spacer material, and forming a dielectric material for a nanosheet stack spacer.

FIG. 29 is a side cross-sectional view of a structure for a semiconductor device method along a gate width direction for the structure depicted in FIG. 28.

FIG. 30 is a side cross-sectional view illustrating one embodiment of a resultant structure following an etch back of the dielectric material for the nanosheet stack spacer that was deposited in

FIG. 29 followed with an epitaxial deposition process for forming the source and drain semiconductor contacts.

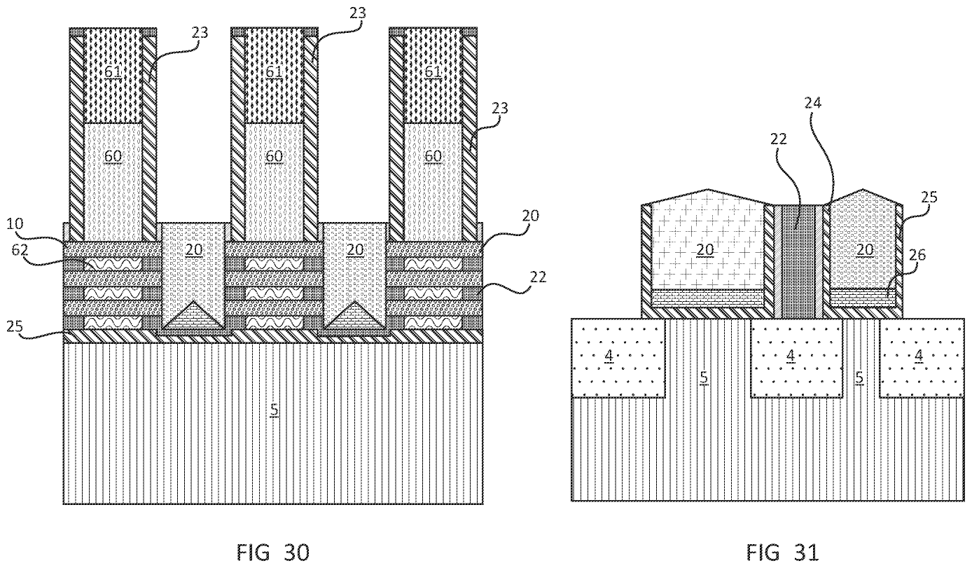

FIG. 31 is a side cross-sectional view of a structure for a semiconductor device method along a gate width direction for the structure depicted in FIG. 30.

### DETAILED DESCRIPTION

Detailed embodiments of the claimed methods, structures and computer products are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. For purposes of the description hereinafter, the terms “upper”, “over”, “overlying”, “lower”, “under”, “underlying”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

In one embodiment, the disclosed structures and method can provide for a gate all around nanosheet device with a self-aligned substrate isolation (SASI) layer and improved source region and drain region epitaxial semiconductor nucleation. Isolation between the suspended nanosheets and the substrate can be provided by a self-aligned substrate isolation layer (also referred to as electrically insulating substrate isolation layer that is aligned to the gate structure) that is positioned between the lowest nanosheet in the channel stack and the substrate. The source and drain semiconductor contacts (e.g., source and drain contacts composed of epitaxially formed semiconductor materials) can be formed using unconfined, partially confined and/or fully confined epitaxial growth through the use of composite spacers.

The disclosed structures and methods can improve the ability to nucleate and grow source and drain epitaxial semiconductor material. The disclosed structures and methods can eliminate relaxation of the epitaxial semiconductor using confinement in the Y-direction from full or partial removal of spacer material on the fin sidewalls for the stack of nanosheets. In some embodiments, the methods and structures of the present disclosure can also provide an etch stop layer for optimal fin recess control. This can provide for substantially no over-etching into the substrate (as well as any punch through stop region that may be present therein, which helps minimize the risk of leakage under the gate structure. In some embodiments, the methods and systems of the present disclosure can also result in a significant gate to substrate capacitance reduction. For example, an etch-stop layer may be preserved under the nanosheet stack, which physically disconnects the bottom of the high-k gate dielectric metal gate of the gate all around structure from the substrate. Additionally, the methods and structures disclosed herein provide for exposed surfaces for source-drain epitaxy nucleation. This can provide a significant advantage for epitaxy formation and potentially strain engineering.

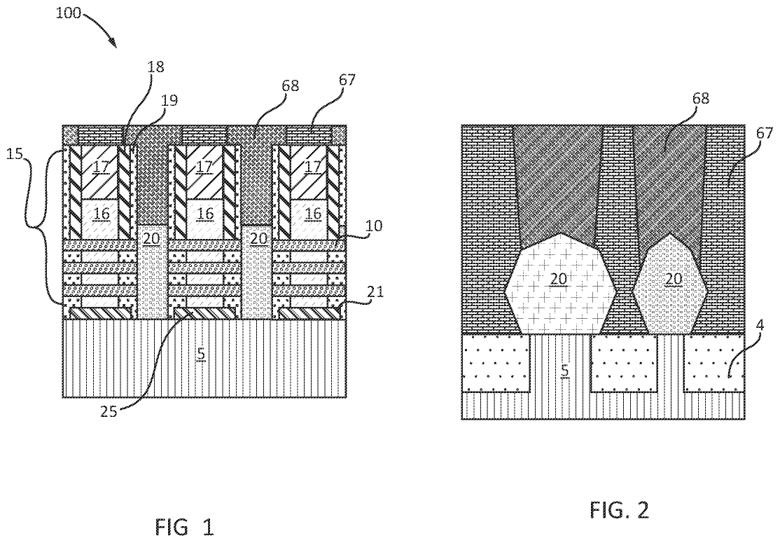

The methods and structures of the present disclosure are now described with reference to FIGS. 1-31.

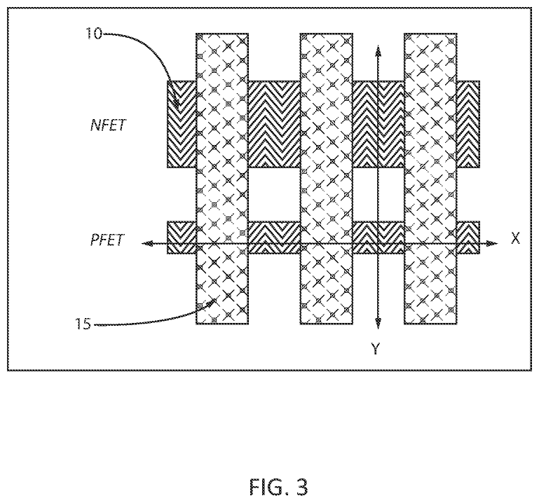

FIG. 1 of a semiconductor device along a gate length direction for a device that includes a gate all around nanosheet channel region with a self-aligned substrate isolation and sites for improved source-drain epitaxial nucleation. FIG. 1 is a side cross-sectional view of a semiconductor device along a gate length direction X-X (also referred to a x-direction) of the device. FIG. 2 is a side cross-sectional view of a semiconductor device along a gate width direction Y-Y (also referred to as y-direction) for the structure depicted in FIG. 1. FIG. 3 is a top down view illustrating the relationship between the side cross-sectional views illustrated in FIGS. 1 and 2, in which the cross-section line identified by X-X is the line from which the cross section illustrated in FIG. 1 is taken, and the cross-section line identified by Y-Y is the line from which the cross section illustrated in FIG. 2 is taken.

In one aspect, a semiconductor device 100 is provided that includes a stack of nanostructure material layers 10 (also referred to as nanosheets 10) overlying a substrate 5, wherein a gate all around structure 15 is present on a channel region portion for the stack of nanostructure material layers 10. The term gate all around denotes that the gate structure that encloses the channel region from both a frontside and backside of the channel. In some embodiments, a conformal dielectric layer is formed on suspended channels of a multiple channel region device, such as a vertically stacked nanosheet or nanowire structure. Thereafter, a gate conductive is formed, in which a single gate structure may enclose a plurality of channel regions having the conformal gate dielectric present thereon. In some instances, the gate all around structure 15 may include a conformal gate dielectric layer (not shown) composed of a high-k gate dielectric material, and a gate conductor 16 of an elemental metal (which may be referred to as a metal gate). A high-k gate dielectric may have a dielectric constant greater than silicon, and in some embodiments may be hafnium based, e.g., be composed of hafnium oxide. The combination of the high-k gate dielectric and the metal gate conductor may be referred to as an HKMG gate structure.

The nanostructure material layer 10 may be nanosheets. A “nanosheet” is a two-dimensional nanostructure with thickness in a scale ranging from 1 nm to 100 nm. In other embodiments, the nanostructure material layers 10 may be a nanowire. A “nanowire” is similar to a nanosheet, yet has a substantially circular or oblong cross-section. In one example, the nanosheets and/or nanowires may be composed of a type IV semiconductor, such as silicon (Si), germanium (Ge) and/or silicon germanium (SiGe). The nanosheets and/or nanowires may also be provided by a type III-V semiconductor material, such as gallium arsenide (GaAs).

Referring to FIGS. 1 and 2, source and drain semiconductor contacts 20 are present on each side of the gate all around (GAA) structure 15. The source and drain semiconductor contacts 20 are composed of epitaxial semiconductor material. The term “epitaxial material” denotes a material that is formed using epitaxial growth. The terms “epitaxial growth and/or deposition” means the growth of a semiconductor material on a deposition surface of a semiconductor material, in which the semiconductor material being grown has substantially the same crystalline characteristics as the semiconductor material of the deposition surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation. The source and drain semiconductor contacts 20 are in direct contact with edges of the nanosheets 10 for the channel region portion for the stack of nanostructure material layers.

FIGS. 1 and 2 further illustrate a gate spacer that is present between the source and drain semiconductor contacts 20 and the gate all around structure 15. The embodiment depicted in FIGS. 1 and 2 include a gate space structure that does not confine the source and drain semiconductor contacts 20 during the epitaxial growth process used in their formation. The gate spacer depicted in FIGS. 1 and 2 may be a composite structure that includes an inner spacer 18 and an outer spacer 19. In some examples, the inner spacer 18 and the outer spacer 19 may be composed of different material compositions. For example, a first material can provide the outer spacer 19 including a base portion 21 of the gate spacer having the L-shaped geometry. Further, a second material provides the inner spacer 18. The second material that provides the inner spacer 18 also provides a material composition for the electrically insulating substrate isolation layer 25. This is one example of source and drain contacts that are formed using an unconstrained epitaxial growth method from the nanosheets, as depicted in FIG. 2. More particularly, in one embodiment, the source and drain semiconductor contacts 20 are not confined by dielectric sidewalls. In this example, due to the unconstrained epitaxial growth, the semiconductor material that provides the source and drain contacts 20 may be multi-faceted, e.g., have multiple faces.

Referring to FIGS. 1 and 2, the semiconductor device 100 further includes an electrically insulating substrate isolation layer 25 that is aligned to be between the gate all around structure 15, the gate spacer, and the substrate 5. In some embodiments, the base portion 21 of the gate spacer has an L-shaped geometry including a portion that warps over an upper surface of the electrically insulating substrate isolation layer 25. In some embodiments, the electrically insulating isolation layer 25 is a self-aligned substrate isolation (SASI) layer that provides for isolation of the bottom channel regions in the nanosheet stack 10. The self-aligned substrate isolation (SASI) layer 25 avoids the need for punch through stopper implants that can result in the formation of a parasitic channel.

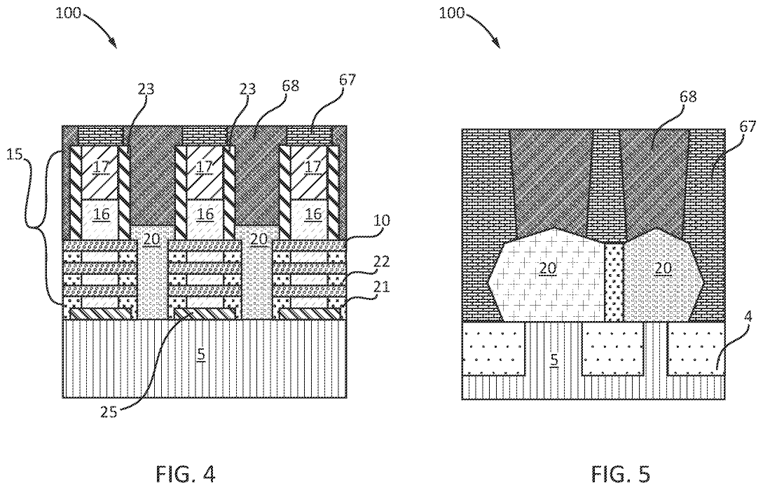

FIGS. 4 and 5 illustrate another embodiment of the present disclosure in which the semiconductor device 100 includes a gate all around nanosheet channel region with a self-aligned substrate isolation 25 and sites for improved source-drain epitaxial nucleation using partial confinement spacers. It is noted that the embodiments depicted in FIGS. 4 and 5 are similar to the embodiments that have been described with reference to FIGS. 1-3. Therefore, the above description of the elements having the reference numbers depicted in FIGS. 1-3 are applicable for the description of at least one embodiment of the elements having the same reference numbers that are illustrated in FIGS. 4 and 5. One difference between the embodiments described in FIGS. 1-3, and the embodiments described in FIGS. 4 and 5 is that the spacer design of the embodiment that is depicted in FIGS. 4 and 5 provides for at least partial constraint of the epitaxial growth of the semiconductor material for the source and drain semiconductor contacts 20.

Referring to FIG. 4, in some examples, the source and drain semiconductor contacts 20 are partially confined by a spacer material 22 in direct contact between two adjacent source and drain semiconductor contacts 20 along a single sidewall. In this embodiment, the gate spacer can include an upper gate portion (upper gate spacer 23) atop the stack of nanostructure material layers and a lower gate portion, as depicted in FIG. 4. The lower gate portion may also be referred to as a nanosheet stack spacer 22. The upper gate spacer 23 and the nanosheet stack spacer 22 may have different compositions. For example, a first material provides an upper gate spacer 23 having a same composition as the electrically insulating substrate isolation layer 25, and a second material may provide the nanosheet stack spacer 22 having a same composition as the base portion 21 of the gate spacer having the L-shaped geometry. In one embodiment, the source and drain semiconductor contacts 20 are only partially confined by dielectric sidewalls (provided by the dielectric material from the nanosheet stack spacer 22).

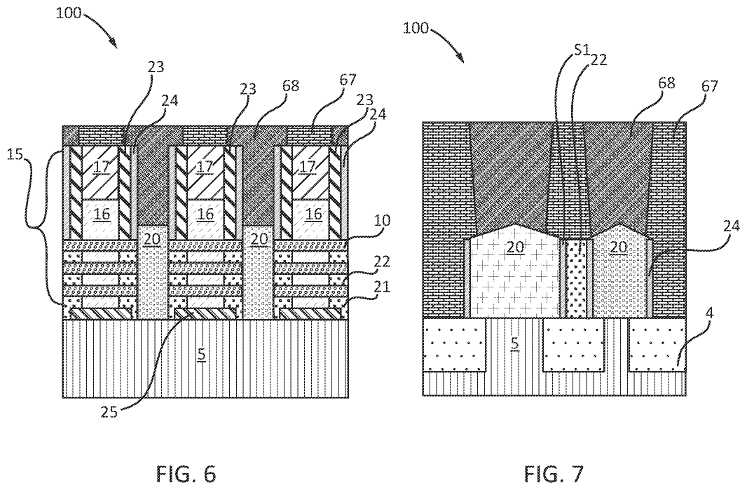

FIGS. 6 and 7 illustrate one embodiment of a semiconductor device 100 that includes a gate all around nanosheet channel region with a self-aligned substrate isolation and sites for improved source-drain epitaxial nucleation using full confinement spacers. It is noted that the embodiments depicted in FIGS. 6 and 7 are similar to the embodiments that have been described with reference to FIGS. 1-3. Therefore, the above description of the elements having the reference numbers depicted in FIGS. 1-3 are applicable for the description of at least one embodiment of the elements having the same reference numbers that are illustrated in FIGS. 6 and 7.

In one embodiment, the semiconductor device 100 includes a stack of nanostructure material layers 10 overlying a substrate 5, in which a gate all around structure 15 is present on a channel region portion for the stack of nanostructure material layers 10. In some embodiments, source and drain semiconductor contacts 10 are present on each side of the gate all around structure 15, and the source and drain semiconductor contacts 20 are present in direct contact with edges of the channel region portion for the nanosheets 5 of the stack of nanostructure material layers.

The semiconductor device 100 may include a composite gate spacer on the gate all around structure 15. For example, the composite gate spacer includes a confining portion 24 on sidewalls of the source and drain contacts 20. In one embodiment, a connecting portion of the spacer (provided by the material having reference number 22) may be in contact between two confining portion spacers 24 on adjacently positioned source and drain semiconductor contacts 20.

The semiconductor device 100 also includes an electrically insulating substrate isolation layer 25 aligned to be between the gate all around structure 15, the composite gate spacer and the substrate 5. In this example, a base portion 21 of the composite gate spacer has an L-shaped geometry including a portion that warps over an upper surface of the electrically insulating substrate isolation layer. In some embodiments, the electrically insulating isolation layer 25 is a self-aligned substrate isolation (SASI) layer. This avoids the need for punch through stopper implants that can result in the formation of a parasitic channel.

In some embodiments, the confining portion 24 of the composite spacer on the sidewalls of the source and drain contacts 20 and retains epitaxial growth of the source and drain contacts 20 to provide source and drain contact sidewalls S1 that are planar. In one example, the composite gate spacer includes an inner gate spacer 23, a nanosheet stack spacer 22, and outer gate spacer 24. Each of these spacers can be composed of different composition dielectric material. For example, a first material can provide the nanosheet stack spacer 22 including at least the base portion 21 of the gate spacer having the L-shaped geometry. A second material provides the inner gate spacer 22. In some embodiments, the electrically insulating substrate isolation layer 25 may also have a composition that is equal to the second material composition of the inner gate spacer 22. A third material provides the outer gate spacer 24.

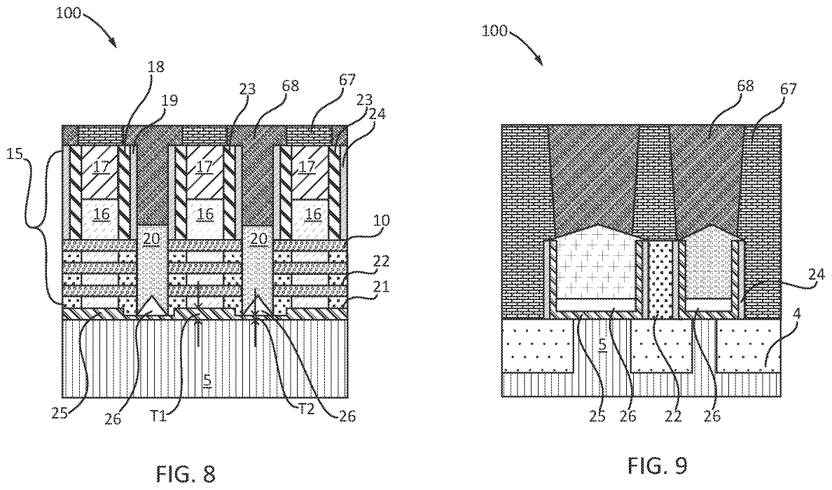

FIGS. 8 and 9 illustrate a semiconductor device along a gate length direction for a device that includes a gate all around nanosheet channel region with a substrate isolation layer 25 having different thicknesses and sites for improved source-drain epitaxial nucleation using full confinement spacers. It is noted that the embodiments depicted in FIGS. 8 and 9 are similar to the embodiments that have been described with reference to FIGS. 1-3. Therefore, the above description of the elements having the reference numbers depicted in FIGS. 1-3 are applicable for the description of at least one embodiment of the elements having the same reference numbers that are illustrated in FIGS. 8 and 9. One difference between the embodiments described in FIGS. 1-3, and the embodiments described in FIGS. 8 and 9 is that the substrate isolation layer 25 design of the embodiment that is depicted in FIGS. 8 and 9 extends across the entirety of the substrate instead of being segmented as the embodiment depicted in FIGS. 1-3.

In one embodiment, the semiconductor device 100 can include a stack of nanostructure material layers 10 overlying a substrate 5. Similar to the above described examples, the nanostructure material layer 10 may be nanosheets. A gate all around structure 15 can be present on a channel region portion for the stack of nanostructure material layers. Source and drain semiconductor contacts 20 can be present on each side of the gate all around structure. The source and drain semiconductor contacts 20 are in direct contact with edges of the channel region portion for the stack of nanostructure material layers. In some embodiments, a gate spacer is present on the gate all around structure, wherein the gate spacer including a confining portion 24 on sidewalls of the source and drain contacts 20. In some embodiments, the device includes an electrically insulating substrate isolation layer 25 having a first thickness T1 aligned to be between the gate all around structure 15, the gate spacer 21 and the substrate 5. The electrically insulating substrate isolation layer 25 also has a second thickness T2 present between the source and drain semiconductor contacts 20 and the substrate 5. In some embodiments, a base portion of the gate spacer 21 has an L-shaped geometry including a portion that warps over an upper surface of a portion of the electrically insulating substrate isolation layer 25 having the first thickness T1. In some embodiments, the first thickness T1 of the electrically insulating substrate isolation layer is greater than the second thickness T2. In some embodiments, this avoids the need for punch through stopper implants that can result in the formation of a parasitic channel.

In some embodiments, the gate spacer is a composite gate spacer including a confining portion 24 on sidewalls of the source and drain contacts 20. The composite gate spacer can include confining portions 24 on sidewalls of the source and drain contacts 20 to epitaxial growth of the source and drain contact 20 to provide source and drain sidewalls S1 that are planar. The composite gate spacer may include an inner gate spacer 23, a nanosheet stack spacer 22, and outer gate spacer 24. In one example, a first material provides the nanosheet stack spacer including that at least the base portion 21 of the gate spacer having the L-shaped geometry, a second material provides the inner gate spacer 23 and a third material provides the outer gate spacer 24. In one embodiment, the second material that provides the inner gate spacer 23 provides a material composition for the electrically insulating substrate isolation layer 25. In some examples, an air gap 26 is present between the source and drain contacts 20 and a portion of the electrically insulating substrate isolation layer 25 having the second thickness T2.

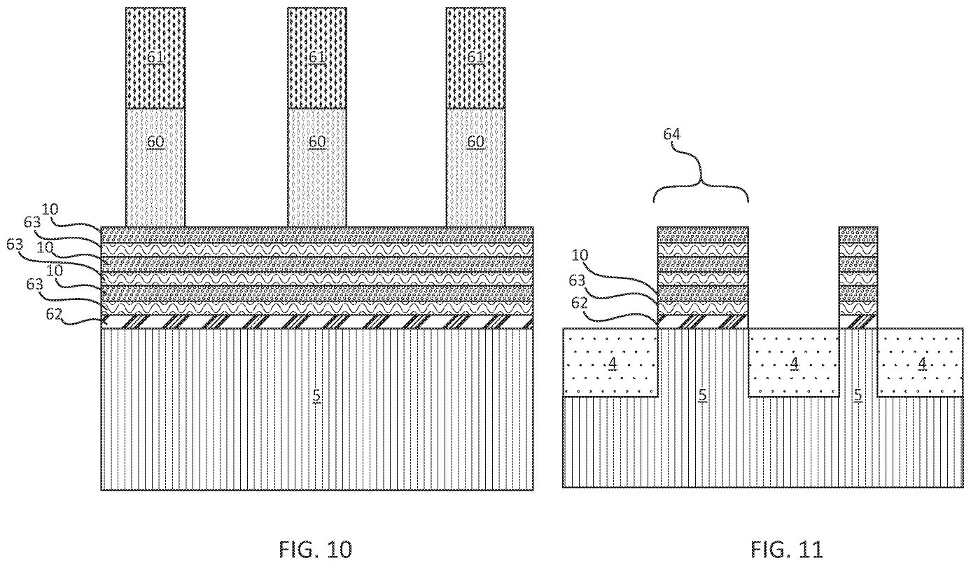

The structures illustrated in FIGS. 1-9 are now described in greater detail in accordance with the following embodiments of a method for forming a semiconductor device. It is noted that the following methods are only some examples of methods for forming the structures depicted in FIGS. 10-31.

FIGS. 10 and 11 illustrate one embodiment of an initial structure that may be employed in method that provides a gate all around nanosheet devices with self-aligned substrate isolation 25 and improved source drain epitaxy nucleation, in accordance with one embodiment of the present disclosure. The structures depicted in FIGS. 10 and 11 includes a nanosheet fin stack (e.g., including nanosheets), a shallow trench isolation region 4 and a dummy gate structure 61.

The stack of nanosheets may also be provided by a type IV semiconductor material, such as silicon, silicon germanium, etc., or a type III-V semiconductor material, such as gallium arsenide (GaAs). It is noted that any semiconductor material that may serve as the channel region of a field effect transistor may be employed for the nanosheets 10. It is noted that the stack of nanosheets may include a first sacrificial nanosheet 62 that is present on the substrate 5. The first sacrificial nanosheet 62 may be removed and replaced with a dielectric material to provide the electrically insulating substrate isolation layer 25. Nanosheets 10 to provide the channel regions of the semiconductor devices are also present in the stack. A second sacrificial nanosheet 63 is also present in the stack.

Each of the layers in the nanosheets stack may be composed of a type IV semiconductor composition that provides for etch selectivity in forming the electrically insulating substrate isolation layer 25. For example, the nanosheet stack that is present atop the epitaxial semiconductor layer 22 may be a multilayered structure composed of silicon nanosheets 10 which are ultimately processed to provide channel regions of the semiconductor device, while the second sacrificial nanosheets 63 are removed to provide suspended channels are composed of silicon germanium (SiGe30) layer having 30% germanium (Ge) content.

In one example, the first sacrificial nanosheets 62 may be removed and replaced with a dielectric material to provide the electrically insulating substrate isolation layer 25 is composed of a silicon germanium layer (SiGe55) having 55 wt. % germanium.

The stack of the layered semiconductor materials for the nanosheets may be formed using a deposition process, such as epitaxial deposition. The thickness of each layer within the stack of the layered nanosheets may range from 1 nm to 30 nm. In another embodiment, the thickness of each layer within the stack of nanosheets may range from 5 nm to 20 nm.

In some embodiments, the stack of the layered nanosheets is patterned and etched to provide fin structures 64 for transistor devices. To pattern the structure, a mask layer (not shown) may be formed atop the stack of nanosheets. The pattern process sequence may be used in combination with process steps for forming isolation regions 4. In some examples, a hardmask may be used for patterning the stack of nanosheets. In some embodiments, the hardmask may be composed of a nitride, such as silicon nitride.

For example, a pattern (not shown) is produced by applying a photoresist to the surface to be etched; exposing the photoresist to a pattern of radiation; and then developing the pattern into the photoresist utilizing conventional resist developer. Once the patterning of the photoresist is completed, the sections of the nanosheet stack covered by the photoresist are protected while the exposed regions are removed using a selective etching process that removes the unprotected regions. The etch process may include a direction etch process, such as reactive ion etching (RIE).

FIGS. 10 and 11 also illustrate one embodiment of forming a replacement gate structure 60. By “replacement”, e.g., as used to describe the replacement gate structure 60, it is meant that the structure is present during processing of the semiconductor device, but is removed from the semiconductor device prior to the device being completed. As used herein, the term “replacement gate structure” denotes a sacrificial structure that dictates the geometry and location of the later formed functioning gate structure. The “functional gate structure” operates to switch the semiconductor device from an “on” to “off”' state, and vice versa.

In one embodiment, the sacrificial material that provides the replacement gate structure 60 may be composed of any material that can be etched selectively to the at least one of the stack of nanosheets. In one embodiment, the sacrificial material of the replacement gate structure 60 may be composed of a silicon-including material, such as polysilicon. In another embodiment, the sacrificial material of the replacement gate structure may be composed of a dielectric material, such as an oxide or amorphous carbon. The replacement gate structure 60 may be formed using deposition (e.g., chemical vapor deposition) photolithography and etch processes (e.g., reactive ion etching). In some embodiments, a mask structure may be employed as illustrated by reference number 61. The mask structure 61 may be provided using deposition and photolithography steps, and may be employed in combinations with the directional, i.e., anisotropic, etch processes to shape the geometry of the replacement gate structure 61 that is composed of the sacrificial material. Using the mask structure 61, the sacrificial material that provides the replacement gate structure 60 may be etched to provide the gate geometry in accordance with the mask 61 using a directional etch process, such as reactive ion etching.

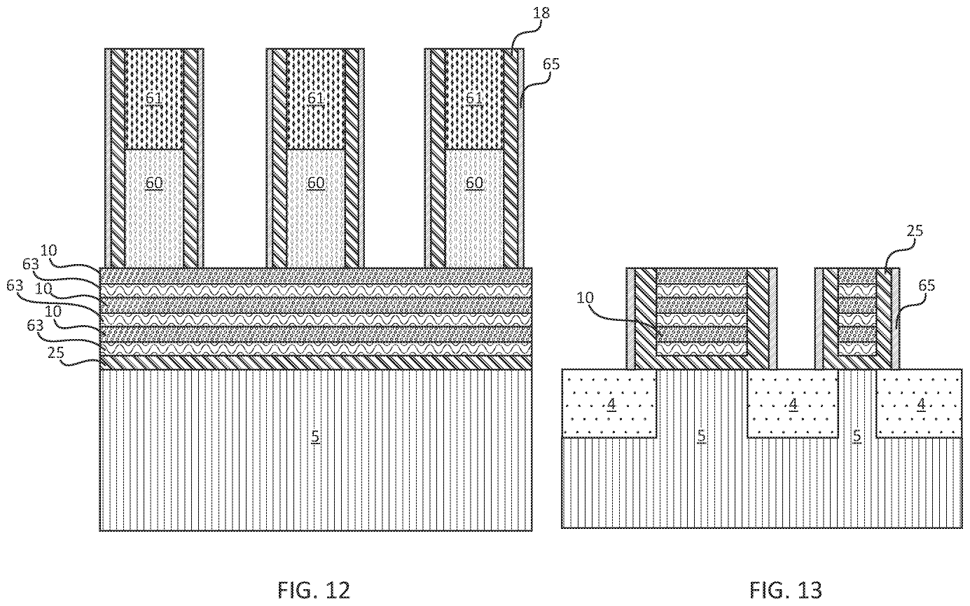

FIGS. 12 and 13 illustrates one embodiment of removing the first sacrificial nanosheet 62 and replacing it with a dielectric material to provide the electrically insulating substrate isolation layer 25. The first sacrificial nanosheets 62 is in the same patterned stack as the nanosheets 10 that provide the channel regions for the transistors. Therefore, by removing the first sacrificial nanosheets 62 and forming the dielectric material within the space provided by removing the first sacrificial nanosheets 62 to provide the electrically insulating substrate isolation layer 25; the electrically insulating substrate isolation layer 25 is self-aligned to the nanosheets 10 that provide channel regions of the device.

In one embodiment, the first sacrificial nanosheets 62 is a silicon germanium having a high germanium content, e.g., 55% germanium within the silicon germanium material. In one embodiment, the first sacrificial nanosheets 62 may be removed by an isotropic etch, e.g., non-directional etch, such as a gas etch, or plasma etch. In some embodiments, the etch process for removing the first sacrificial nanosheets 62 is selective to the other material layers identified by reference numbers 10 and 63 in the stacks that are processed to provide the nanosheets 10 for the channel regions of the semiconductor devices. As used herein, the term “selective” in reference to a material removal process denotes that the rate of material removal for a first material is greater than the rate of removal for at least another material of the structure to which the material removal process is being applied. For example, in one embodiment, a selective etch may include an etch chemistry that removes a first material selectively to a second material by a ratio of 10:1 or greater, e.g., 1000:1. For example, the etch process may remove the silicon and germanium (SiGe) containing material having a germanium content of 55 wt. % of the first sacrificial nanosheet 62 without removing the semiconductor material of silicon (Si) that provides the nanosheets 10 for the channel region, and/or without removing the layers 63 composed silicon and germanium (SiGe) having a germanium (Ge) content of 30%.

FIGS. 12 and 13 illustrates one embodiment of filling the space that is formed by removing the first sacrificial nanosheet 62 with a dielectric material to provide the electrically insulating substrate isolation layer 25, e.g., a self-aligned substrate isolation (SASI) layer. The electrically insulating substate isolation layer 25 is present between the nanosheets 10 for the channel regions of the devices and the substrate 5. Forming the electrically insulating substrate isolation layer 25, e.g., a self-aligned substrate isolation (SASI) layer, may include a process sequence that also forms a gate spacer, i.e., inner spacer 18. The inner spacer 18 may be referred to as a first spacer liner.

The space provided by removing the first sacrificial nanosheet 62 is filled with a dielectric material using deposition and etch back processes to provide the electrically insulating substate isolation layer 25. For example, the electrically insulating substate isolation layer 25 may be composed of a dielectric material, such as silicon nitride or silicon oxide, and may be formed using a deposition process, such as chemical vapor deposition (CVD) or atomic layer deposition (ALD). In some embodiments, following deposition of the material for the electrically insulating substate isolation layer 25, an etch back process, such as reactive ion etching (RIE) may be employed to further tailor the geometry of the layer. The etch back process may include a direction etch, such as reactive ion etching (RIE). The inner gate spacer 18 that is abutting the replacement gate structure 60 may also be formed using deposition and etch back processes, as described for forming the electrically insulating substate isolation layer 25.

FIGS. 12 and 13 may also depict forming a protective spacer liner 65. The protective spacer line 65 is composed of a dielectric material that can be deposited using a conformal deposition process, such as chemical vapor deposition (CVD), e.g., plasma enhanced chemical vapor deposition and/or metal organic chemical vapor deposition, or atomic layer deposition (ALD). In one example, the protective spacer layer 65 is composed of an oxide, e.g., silicon oxide, or nitride, e.g., silicon nitride. Following deposition, an anisotropic etch process, such as reactive ion etching (RIE), may be used to remove horizontally oriented portions of the dielectric layer, wherein the vertically orientated portions remain to provide the protective spacer liner 65. Following the formation of the protective spacer liner 65, the fins of the nanosheets 10, 63 may be patterned.

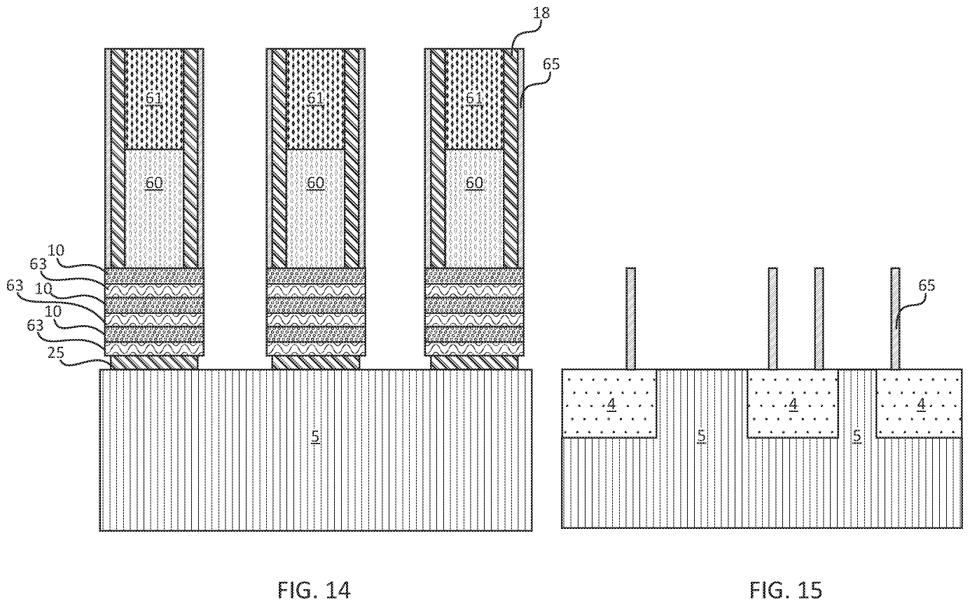

FIGS. 14 and 15 illustrate one embodiment of an anisotropic fin recess, and an isotropic etch back of the gate spacer material provided by the inner gate spacer 18. Following the formation of the protective spacer liner 65, the exposed portions of the stack of nanostructures 10, 63 may be etched. This can provide the space in which the source and drain semiconductor contacts 20 are subsequently formed. The etch process for recessing the stack of nanostructures may be an anisotropic etch, such as reactive ion etching (RIE), and may be referred to as a nanostructure stack recess.

Following the anisotropic etching to recess the fin stack, an isotropic etch, such as a plasma etch, may be performed to etch back the gate spacer material, e.g., etch back the material for the inner gate spacer 18. Referring to FIG. 13, the isotropic etch can remove an exposed portion of the electrically insulating substrate isolation layer 25, e.g., a self-aligned substrate isolation (SASI) layer. This exposes the semiconductor substrate 5 in the portions of the structure at which the source and drain semiconductor contacts 20 are subsequently formed. The semiconductor substrate 5 may be composed of a silicon containing material, e.g., silicon (Si).

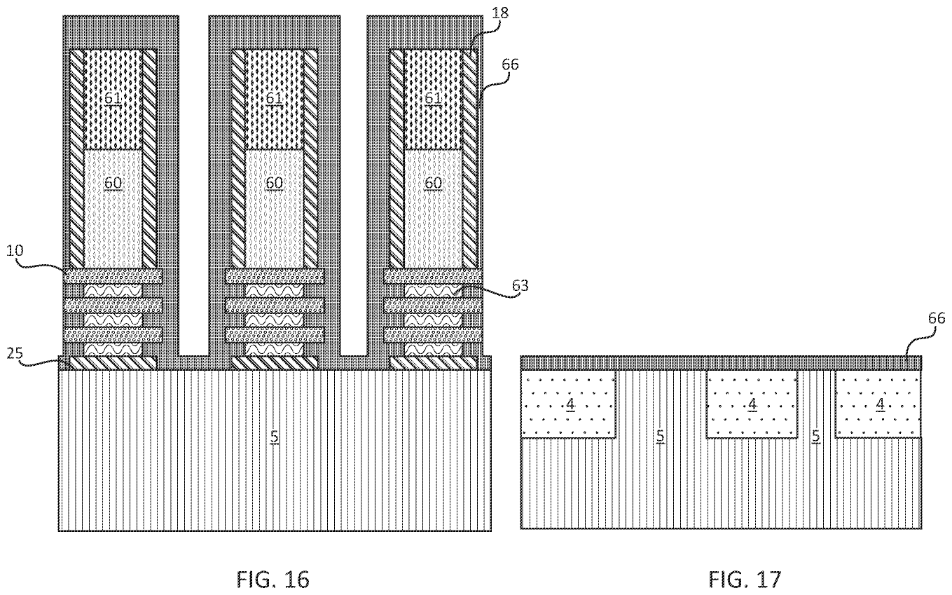

FIGS. 16 and 17 illustrate one embodiment of deposition of the dielectric material for forming the outer spacer 19. Before forming the dielectric material for the outer spacer 19, the protective liner 65 may be removed. For example, the protective liner 65 may be removed using a selective etch process. Thereafter, the ends of the second sacrificial nanosheets 63 are indented relative to the nanosheets identified by reference number 10 in the patterned stacks. For example, the second nanosheets 63 may be composed of silicon germanium (SiGe30) layer having 30% germanium (Ge) content, i.e., low germanium (Ge) content silicon germanium (SiGe). Indentation may include an etch process that isotropically removes the low germanium (Ge) content silicon germanium (SiGe) relative to the silicon (Si) material of the nanosheets 10.

In a following step, the dielectric material 66 for the outer spacer 19 may be conformally deposited using a chemical vapor deposition process (CVD) process, such as plasma enhanced chemical vapor deposition (PECVD) or metal organic chemical vapor deposition (MOCVD). In yet further embodiments, the dielectric material for the outer spacer 19 may be atomic layer deposition (ALD). The outer spacer may be composed of a nitride or oxide material. For example, the outer spacer 19 may be composed of a nitride, such as silicon nitride, or the outer spacer may be composed of an oxide, such as silicon oxide.

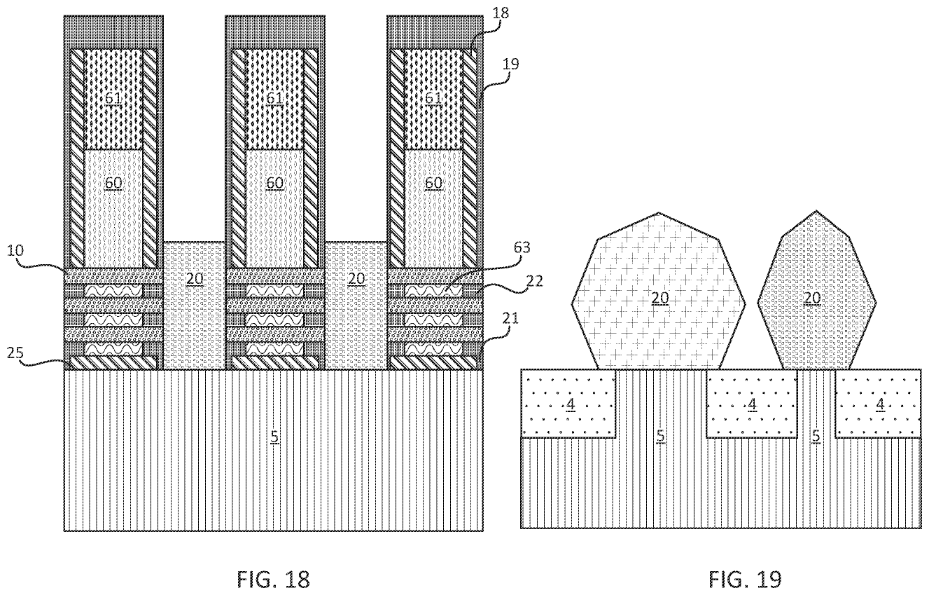

FIGS. 18 and 19 illustrate a selective isotropic etch back of the dielectric material 66 for the outer spacer 19 and forming the source and drain semiconductor contacts 20. The selective isotropic etch back may be a gas etch or plasma etch. The isotropic etch may be continued until enough of the dielectric material for the outer spacer 19 are removed so that the edge faces of the nanosheets 20 that provide the channel regions of the devices are exposed. Following this step, the base of the outer spacer 19 may have an L-shaped geometry, in which a portion of the spacer extends atop the upper surface of the electrically insulating substrate isolation layer 25, e.g., a self-aligned substrate isolation (SASI) layer.

Still referring to FIGS. 18 and 19, the source and drain semiconductor contacts 20 may be formed by an epitaxial deposition method. As used herein, the term “drain” means a doped region in semiconductor device located at the end of the channel region, in which carriers are flowing out of the transistor through the drain. The term “source” is a doped region in the semiconductor device, in which majority carriers are flowing into the channel region. The source and drain regions may be composed of epitaxial semiconductor material that is doped to an n-type or p-type dopant. In some embodiments, the epitaxial semiconductor material that provides the source and drain contact regions 20 may be composed of silicon (Si), germanium (Ge), silicon germanium (SiGe), silicon doped with carbon (Si:C), or the epitaxial semiconductor material that provides the source and drain regions may be composed of a type III-V compound semiconductor, such as gallium arsenide (GaAs).

The epitaxial semiconductor material for the source and drain semiconductor contacts 20 may be in situ doped to a p-type or n-type conductivity. The term “in situ” denotes that a dopant, e.g., n-type or p-type dopant, is introduced to the base semiconductor material, e.g., silicon or silicon germanium, during the formation of the base material. For example, an in situ doped epitaxial semiconductor material may introduce n-type or p-type dopants to the material being formed during the epitaxial deposition process that includes n-type or p-type source gasses. In the embodiments in which the semiconductor device being formed has p-type source and drain regions, and is referred to as a p-type semiconductor device, the doped epitaxial semiconductor material is doped with a p-type dopant to have a p-type conductivity. As used herein, “p-type” refers to the addition of impurities to an intrinsic semiconductor that creates deficiencies of valence electrons. In a type IV semiconductor, such as silicon, examples of p-type dopants, i.e., impurities, include but are not limited to, boron, aluminum, gallium and indium. As used herein, “n-type” refers to the addition of impurities that contributes free electrons to an intrinsic semiconductor. In a type IV semiconductor, such as silicon, examples of n-type dopants, i.e., impurities, include but are not limited to antimony, arsenic and phosphorous. Referring to FIG. 19, the source and drain semiconductor contact regions 20 may be provided for at least two devices on a single substrate 5, e.g., an n-FET device and a p-FET device.

Referring to FIGS. 18 and 19, the epitaxial growth process employs the semiconductor surfaces of both the substrate 5, i.e., the exposed portions of the substrate between the segments of the electrically insulating substrate isolation layer 25, e.g., a self-aligned substrate isolation (SASI) layer, and from the exposed edges of the nanosheets 10 that provide the channel regions.

Referring back to FIGS. 1-3, in a following process sequence, the method can continue with removing the replacement gate structure 60 and forming a functional gate structure 15, which may include a high-k gate dielectric and a metal gate conductor. This process sequence may be referred to as substituting a gate all around structure 15 for the replacement gate structure 60.

In some embodiments, the process sequence for removing the replacement gate structure, e.g., including the sacrificial material for the replacement gate structure 60 and the mask structure identified by reference number 61, can begin with depositing an interlevel dielectric layer 67. The interlevel dielectric layer 67 may have a composition selected from the group consisting of silicon-containing materials such as SiO₂, Si₃N₄, SiOₓN_{y}, SiC, SiCO, SiCOH, and SiCH compounds; the above-mentioned silicon-containing materials with some or all of the Si replaced by Ge; carbon-doped oxides; inorganic oxides; inorganic polymers; hybrid polymers; organic polymers such as polyamides or SiLK™; other carbon-containing materials; organo-inorganic materials such as spin-on glasses and silsesquioxane-based materials; and diamond-like carbon (DLC, also known as amorphous hydrogenated carbon, α-C:H). The interlevel dielectric layer may be deposited using a deposition process, such as spin on deposition (SOD) followed by a planarization process, such as chemical mechanical planarization (CMP). The planarization process may be continued until the upper surface of the interlevel dielectric layer is coplanar with the upper surface of the mask structure identified by reference number 61.

The mask structure 61 and replacement gate structure 60 may then be removed using a selective etch process. More particularly, removing the replacement gate structure 60 using a selective etch process may include removing the sacrificial material for the replacement gate structure 60 and the mask structure identified by reference number 61, without removing the semiconductor material layers in the stack for providing the nanosheets 20.

In some embodiments, once the sacrificial gate structure 60 is removed, the nanostructure layers may be processed to provide nanostructures, e.g., nanowires and/or nanosheets. For example, the semiconductor material layers identified by reference number 63 may be removed selectively to the semiconductor material layers identified by reference number 10. This provides a plurality of suspended semiconductor material layers, which ultimately provided suspended nanosheet channels 5.

In some embodiments, the suspended structure, e.g., semiconductor material layer 10, may be further processed to a geometry in the nanometer regime. For example, the semiconductor material layers 10 (also referred to as nanosheets 10) may be thinned by a process that includes controlling thinning of the silicon (Si) containing nanosheets 5, which can include ozone (O₃) oxidation, SC1 chemistry oxidation and/or dry oxidation. The geometry may also be modified to provide nanowires.

The method continues with the forming a functional gate structure 15 in the space that was created by removing the replacement gate structure 60. In some embodiments, the functional gate structure 15 is a gate all around structure including a high-k gate dielectric and a metal gate conductor. The gate dielectric may be a high-k dielectric material, such as hafnium oxide (HfO₂). The gate dielectric for the gate all around structure may be deposited using chemical vapor deposition or atomic layer deposition and is present on the entirety of the exterior surfaces of the suspended nanosheets 10. The metal gate conductor for the gate structure 15 may encapsulate the suspended nanosheets 10 including the gate dielectric present on the exterior surfaces of the suspended nanosheets 10. The gate conductor may be composed of a metal, such as tungsten (W) or an n-type or p-type work function metal, e.g., titanium nitride. It is noted that the prior examples are provided for illustrative purposes only, and are not intended to limit the teachings of this disclosure solely thereto. For example, the gate conductor for the gate all around structure that provides the functional gate structure 15, e.g., gate all around gate structure, may be composed of other conductive materials, such as a doped semiconductor, e.g., n-type doped polysilicon. Each of the aforementioned layers may be formed using a deposition method, such as chemical vapor deposition, atomic layer deposition, plating, physical vapor deposition, etc.

Referring to FIG. 1, the gate structure of the present devices identified by reference number 15 may be a gate all around structure. In some embodiments, a conformal dielectric layer is formed on suspended channels of a multiple channel region device, such as a vertically stacked nanosheet or nanowire structure. Thereafter, a gate conductive is formed, in which a single gate structure may enclose a plurality of channel regions having the conformal gate dielectric present thereon. In some instances, the gate all around structure may include a conformal gate dielectric layer composed of a high-k gate dielectric material, and a gate conductor of an elemental metal (which may be referred to as a metal gate). A high-k gate dielectric may have a dielectric constant greater than silicon, and in some embodiments may be hafnium based, e.g., be composed of hafnium oxide.

FIGS. 1-3 also depict forming interconnect contacts 68. In some embodiments, an interlevel dielectric layer 67 is first deposited and then etched to form via openings to the underlying contacts, e.g., source and drain semiconductor contacts 20. Thereafter, the via openings are then filled with an electrically conductive material, such as a metal, e.g., copper, to provide an interconnect contact 68. Thereafter, a deposition, pattern and fill sequence is repeated to forms lines. This may be referred to a single damascene method for forming lines and vias. However, dual damascene sequences are also applicable. The sequence of deposition, pattern and etch are repeated as many times as needed to form each level of metal lines and vias.

The method described with reference to FIGS. 10-19 is one example of a method for forming a device including an electrically insulating substrate isolation layer 25, e.g., a self-aligned substrate isolation (SASI) layer, in which the epitaxial material for the source and drain semiconductor contacts 20 is formed using a non-confined method. It is noted that this is only one embodiment of the present disclosure, and it is not intended that the method by limited to only this example.

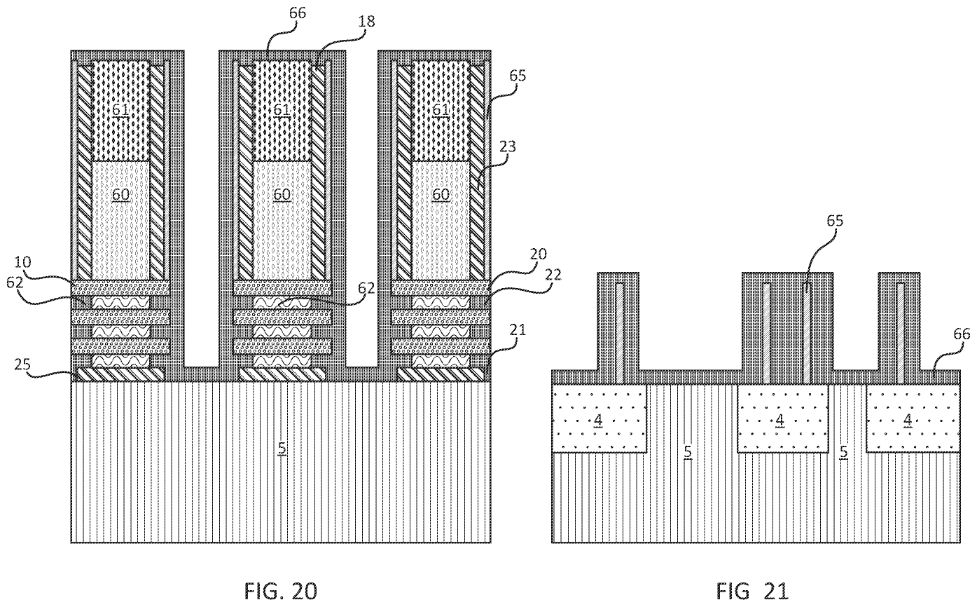

FIGS. 20-23 illustrate some embodiments of methods for forming a semiconductor device that includes the electrically insulating substrate isolation layer 25, e.g., a self-aligned substrate isolation (SASI) layer, in which the epitaxial material for the source and drain semiconductor contacts 20 is formed using a partially confined method.

The method flow illustrated in FIGS. 20-23 begins with an initial structure as illustrated by FIGS. 14 and 15 of the previously described method. It is noted that the methods described with reference to FIGS. 9-19 is similar to the method that is to be described with reference to FIGS. 20-23. Therefore, elements that are depicted in FIGS. 20-23 that have the same reference numbers as elements have already been described with reference to FIGS. 9-19 may share the same description without being repeated. Further, the process flow from FIGS. 9-15 are applicable to the process flow that continues with FIGS. 20-23.

FIGS. 20-21 illustrate forming a dielectric material 66 for the outer spacer 19, in which different from the process flow described with reference to FIGS. 9-19, the protective spacer liner 65 is still present while the dielectric material 66 for the outer spacer 19 is formed (in this embodiment the spacer provided is the nanosheet stack spacer 22). The dielectric material 66 may be conformally deposited using a chemical vapor deposition process, such as plasma enhanced chemical vapor deposition or metal organic chemical vapor deposition. In yet further embodiments, the dielectric material for the outer spacer 19 may be atomic layer deposition. The outer spacer may be composed of a nitride or oxide material. For example, the nanosheet stack spacer 22 may be composed of a nitride, such as silicon nitride, or the outer spacer may be composed of an oxide, such as silicon oxide.

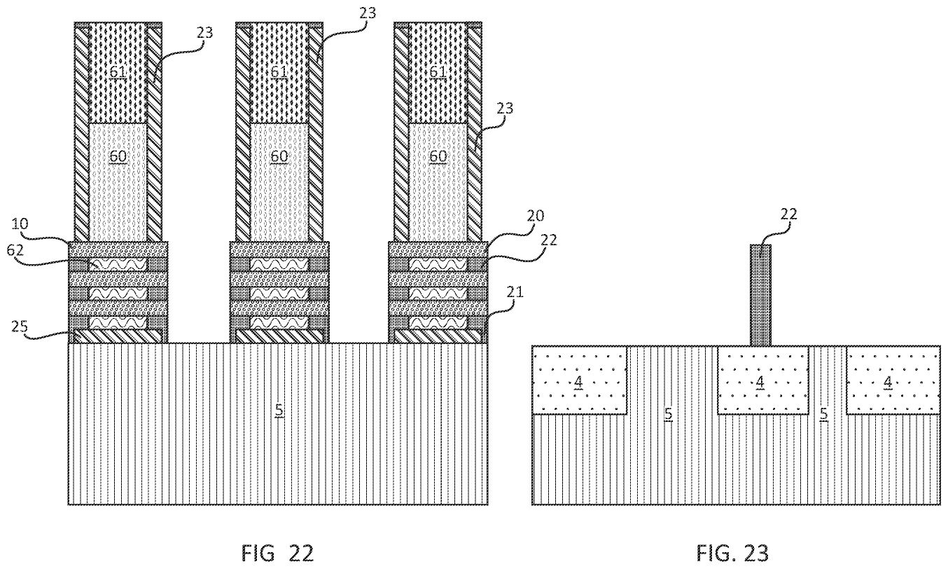

Following formation of the dielectric material 66, a selective isotropic etch back of the dielectric material 66 for the nanosheet stack spacer 22 is performed, which is followed by removing the protective spacer liner 66. FIGS. 22 and 23 illustrate the structure following removing the protective spacer liner 66. The aforementioned etch processes may be selective etch processes. In some embodiment, dielectric sidewall 22 of the dielectric material 66 remains and provides that the subsequently formed source and drain semiconductor contacts 20 are only partially confined.

Referring to FIGS. 4 and 5, the method may continue with forming the source and drain semiconductor contacts 20. The source and drain semiconductor contacts 20 may be formed by an epitaxial deposition method. The epitaxial semiconductor material for the source and drain semiconductor contacts 20 may be in situ doped to a p-type or n-type conductivity. Referring to FIGS. 4 and 5, the epitaxial growth process employs the semiconductor surfaces of both the substrate 5, i.e., the exposed portions of the substrate between the segments of the electrically insulating substrate isolation layer 25, e.g., a self-aligned substrate isolation (SASI) layer, and from the exposed edges of the nanosheets 10 that provide the channel regions. The source and drain semiconductor contacts 20 are only partially confined by dielectric sidewalls 22, as depicted in FIG. 5.

In a following process sequence, the method can continue with removing the replacement gate structure 60 and forming a functional gate structure 15, which may include a high-k gate dielectric and a metal gate conductor. In some embodiments, the process sequence for removing the replacement gate structure, e.g., including the sacrificial material for the replacement gate structure 60 and the mask structure identified by reference number 61, can begin with depositing an interlevel dielectric layer 67. The mask structure 61 and replacement gate structure 60 may then be removed using a selective etch process. More particularly, removing the replacement gate structure 60 using a selective etch process may include removing the sacrificial material for the replacement gate structure 60 and the mask structure identified by reference number 61, without removing the semiconductor material layers in the stack for providing the nanosheets 20.

The method may continue with the forming a functional gate structure 15 in the space that was created by removing the replacement gate structure 60. In some embodiments, the functional gate structure 15 is a gate all around structure including a high-k gate dielectric and a metal gate conductor. FIGS. 4-5 also depict forming interconnect contacts 68.

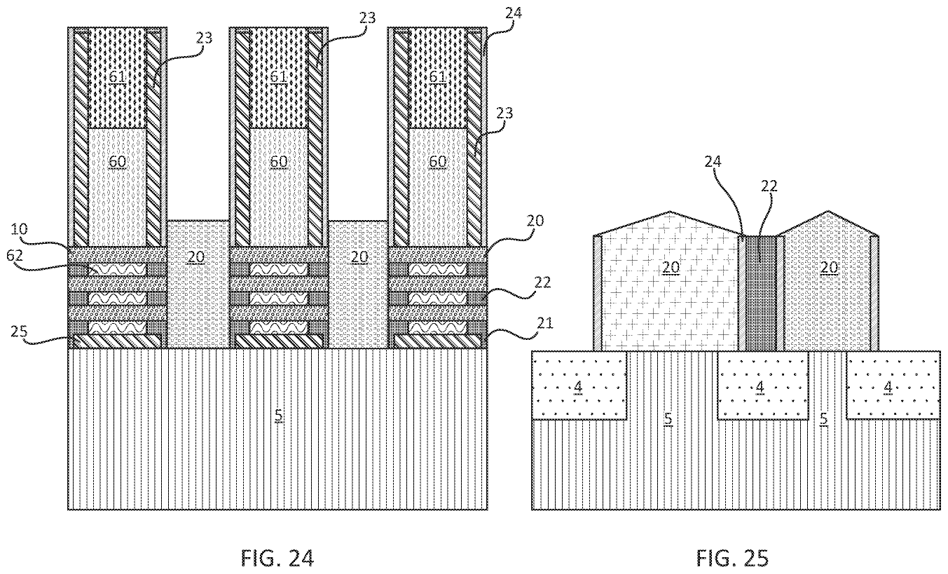

The method described with reference to FIGS. 20-23 may be modified to provide yet another embodiment of the present disclosure, as depicted in FIGS. 6 and 7. FIGS. 6 and 7 illustrate a device that includes a gate all around nanosheet channel region with a self-aligned substrate isolation and sites for improved source-drain epitaxial nucleation using full confinement spacers 24. FIGS. 24 and 25 illustrate process steps that can provide the full confinement illustrated in FIGS. 6 and 7. FIGS. 24 and 25 are process steps that form confinement spacers 24 using a process sequence including the steps described with reference to FIGS. 9-15, 20 and 21. Different from the previous embodiment that removed the protective spacer liner 66 in FIGS. 22 and 23 to provide for only partial confinement of the epitaxial semiconductor material during formation of the source and drain semiconductor contacts 20; in the embodiment depicted in FIGS. 24 and 25 to provide for full confinement of the epitaxial semiconductor material during the formation of the source and drain semiconductor contacts 20 the protective spacer liner 66 is not removed and provides a confinement spacer during epitaxial growth processes used to provide the source and drain semiconductor contacts 20. Following the epitaxial growth processes, in which the confinement spacers 24 fully confine the epitaxially grown material while forming the source and drain semiconductor contacts, the method progresses to removing the replacement gate 60, and forming a functioning gate structure, i.e., gate all around gate structure 15. Back end of the line processing follows to provide interconnects.

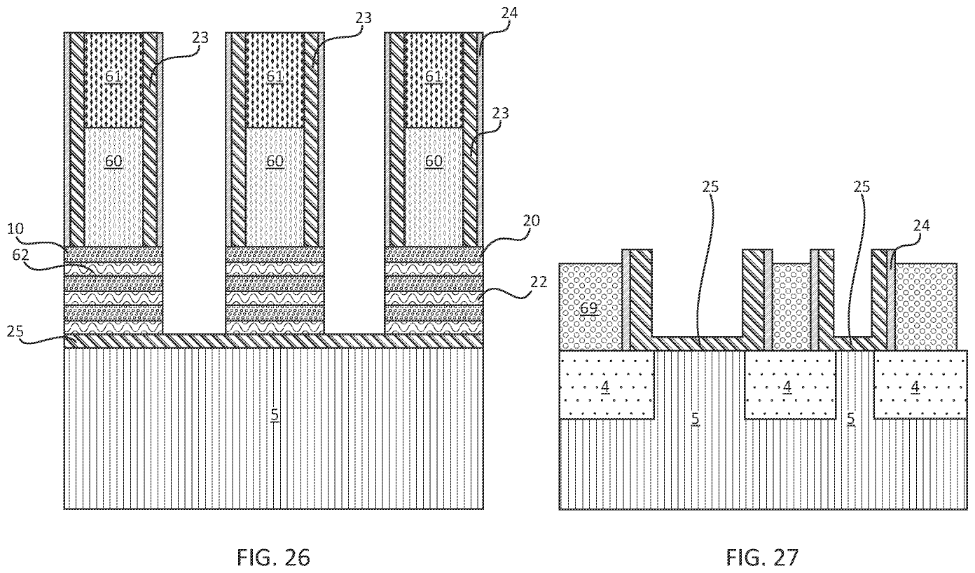

FIGS. 26-31 describe yet another embodiment of a method that can provide a device including an electrically insulating substrate isolation layer 25, e.g., a self-aligned substrate isolation (SASI) layer, in which the epitaxial material for the source and drain semiconductor contacts 20 is formed using a fully confined method. The method flow illustrated in FIGS. 26-31 begins with an initial structure as illustrated by FIGS. 12 and 13 of the previously described method. It is noted that the methods described with reference to FIGS. 9-13 is similar to the method that is to be described with reference to FIGS. 26-31. Therefore, elements that are depicted in FIGS. 26-31 that have the same reference numbers as elements have already been described with reference to FIGS. 9-13 may share the same description without being repeated. Further, the process flow from FIGS. 9-13 are applicable to the process flow that continues with FIGS. 26-31.

FIGS. 26-27 illustrate one embodiment of depositing an organic planarization layer 69 followed by a process step for recessing the organic planarization layer 69, as depicted in FIG. 27. Following formation of the organic planarization layer 69, the method may continue with an anisotropic recess of the nanosheet stacks having the fin geometry.

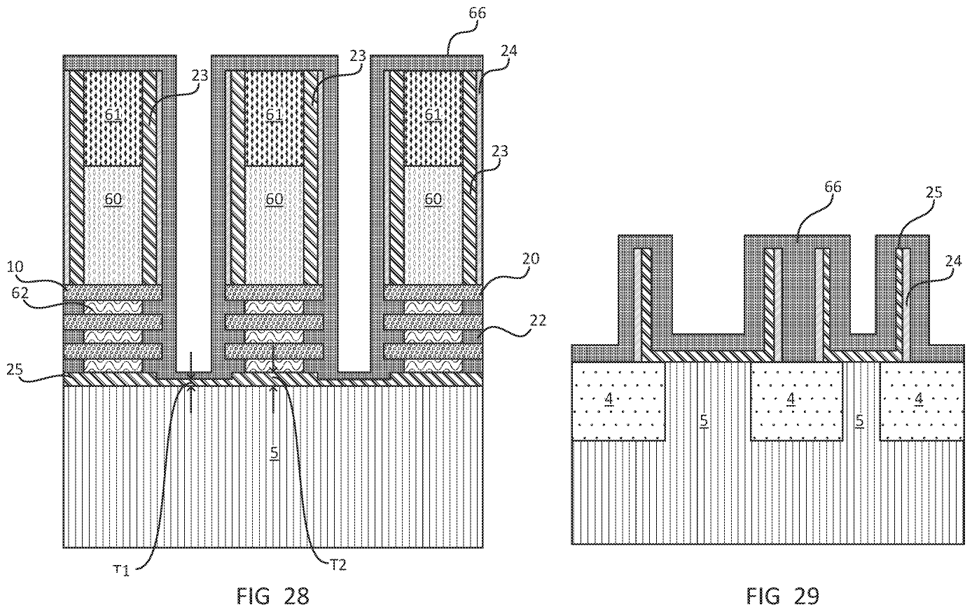

FIGS. 28-29 illustrate a following process step, in which a selective etch process is applied to the structure depicted in FIGS. 26-27, that results in a partial etch back of the gate spacer material. In some embodiments, the selective etch process depicted in FIGS. 28 and 29 is an isotropic etch process. The isotropic etch process may form recesses in the exposed portions of the electrically insulating substrate isolation layer 25, e.g., a self-aligned substrate isolation (SASI) layer. This provides an electrically insulating substrate isolation layer 25 having a first thickness T1 aligned to be between the gate all around structure 15, the gate spacer 21 and the substrate 5. The electrically insulating substrate isolation layer also has a second thickness present between the source and drain semiconductor contacts and the substrate. The second thickness is greater than the first thickness.

FIGS. 28-29 also illustrate forming a dielectric material 66 for the nanosheet stack spacer 22. The dielectric material 66 may be conformally deposited using a chemical vapor deposition process process, such as plasma enhanced chemical vapor deposition or metal organic chemical vapor deposition. In yet further embodiments, the dielectric material for the nanosheet stack spacer 22 may be atomic layer deposition. The nanosheet stack spacer 22 may be composed of a nitride or oxide material. In some embodiments, prior to depositing the dielectric material 66 for the nanosheet stack spacer 22, the ends of the nanosheets 63 may be laterally etched using an isotropic etch. The laterally etching may be referred to as selective indentation of the nanosheets 63 composed of low germanium content silicon germanium. In some embodiments, prior to depositing the dielectric material 66 for the nanosheet stack spacer 22, the organic planarization layer 29 may be removed using a stripping method.

FIGS. 30 and 31 illustrate one embodiment of a resultant structure following an etch back of the dielectric material 66 for the nanosheet stack spacer 22 that was deposited in FIGS. 28 and 29 followed with an epitaxial deposition process for forming the source and drain semiconductor contacts 20. During the epitaxial deposition process, the confinement spacers 24 limit the growth of the epitaxially grown semiconductor material that provides the source and drain semiconductor contacts 20. The epitaxially grown semiconductor material that provides the source and drain semiconductor contacts 20 is grown on the exposed surfaces of nanosheets. An air gap 26 may form at the base of the source and drain semiconductor contacts 20 that separates the majority of the source can drain semiconductor contacts from the electrically insulating substrate isolation layer 25, e.g., a self-aligned substrate isolation (SASI) layer. It is noted that in some embodiments, the confinement spacers 24 may be removed using selective etching following the formation of the source and drain semiconductor contacts 20.

Following the epitaxial growth processes, in which the confinement spacers 24 fully confine the epitaxially grown material while forming the source and drain semiconductor contacts 20, the method progresses to removing the replacement gate 60, and forming a functioning gate structure, i.e., gate all around gate structure 15, as illustrated in FIGS. 7 and 8. Back end of the line processing follows to provide interconnects, as illustrated in FIGS. 7 and 8.

Having described preferred embodiments of a methods and structures for a nanosheet device with aligned isolation and epitaxial growth are disclosed herein, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor device comprising:
a stack of nanostructure material layers overlying a substrate, wherein a gate all around structure is present on a channel region portion for the stack of nanostructure material layers;
source and drain semiconductor contacts on each side of the gate all around structure, the source and drain semiconductor contacts in direct contact with edges of the channel region portion for the stack of nanostructure material layers;
a gate spacer between the source and drain semiconductor contacts and the gate all around structure; and
an electrically insulating substrate isolation layer aligned to be between the gate all around structure, the gate spacer and the substrate, wherein a base portion of the gate spacer has an L-shaped geometry including a portion that warps over an upper surface of the electrically insulating substrate isolation layer.

2. The semiconductor device of claim 1, wherein electrically insulating isolation layer is a self-aligned substrate isolation (SASI) layer.

3. The semiconductor device of claim 1, wherein the gate spacer is a composite structure including an inner spacer and an outer spacer of different material compositions, wherein a first material provides the outer spacer including that at least the base portion of the gate spacer having the L-shaped geometry, and a second material provides the inner spacer.

4. The semiconductor device of claim 3, wherein the second material that provides the inner spacer provides a material composition for the electrically insulating substrate isolation layer.

5. The semiconductor device of claim 1, wherein the source and drain semiconductor contacts are not confined by dielectric sidewalls.

6. The semiconductor device of claim 1, wherein the source and drain semiconductor contacts are partially confined by a spacer material in direct contact between two adjacent source and drain semiconductor contacts along a single sidewall.

7. The semiconductor device of claim 1, wherein gate spacer includes an upper portion atop the stack of nanostructure material layers that includes two different materials, wherein a first material provides an outer spacer having a same composition the base portion of the gate spacer having the L-shaped geometry, and a second material provides an inner spacer and has a same composition as the electrically insulating substrate isolation layer.

8. The semiconductor device of claim 1, wherein gate spacer includes an upper portion atop the stack of nanostructure material layers having a single composition that is composed of a dielectric material having a same composition as the electrically insulating substrate isolation layer.

9. A semiconductor device comprising:
a stack of nanostructure material layers overlying a substrate, wherein a gate all around structure is present on a channel region portion for the stack of nanostructure material layers;
source and drain semiconductor contacts on each side of the gate all around structure, the source and drain semiconductor contacts in direct contact with edges of the channel region portion for the stack of nanostructure material layers;
a composite gate spacer on the gate all around structure, wherein the composite gate spacer including a confining portion on sidewalls of the source and drain semiconductor contacts; and
an electrically insulating substrate isolation layer aligned to be between the gate all around structure, the composite gate spacer and the substrate, wherein a base portion of the composite gate spacer has an L-shaped geometry including a portion that warps over an upper surface of the electrically insulating substrate Isolation layer.

10. The semiconductor device of claim 9, wherein electrically insulating isolation layer is a self-aligned substrate isolation (SASI) layer.

11. The semiconductor device of claim 9, wherein the confining portion on sidewalls of the source and drain contacts for the composite gate spacer retains epitaxial growth of the source and drain contact to provide source and drain sidewalls that are planar.

12. The semiconductor device of claim 9, wherein the composite gate spacer includes an inner gate spacer, a nanosheet stack spacer, and outer gate spacer, wherein a first material provides the nanosheet stack spacer including that at least the base portion of the composite spacer having the L-shaped geometry, a second material provides the inner gate spacer and a third material provides the outer gate spacer.

13. The semiconductor device of claim 12 wherein the second material that provides the inner spacer provides a material composition for the electrically insulating substrate isolation layer.

14. The semiconductor device of claim 12 wherein the source and drain semiconductor contacts are partially confined by a spacer material in direct contact between two adjacent source and drain semiconductor contacts along a single sidewall.

15. A semiconductor device comprising:
a stack of nanostructure material layers overlying a substrate, wherein a gate all around structure is present on a channel region portion for the stack of nanostructure material layers;
source and drain semiconductor contacts on each side of the gate all around structure, the source and drain semiconductor contacts in direct contact with edges of the channel region portion for the stack of nanostructure material layers;
a gate spacer on the gate all around structure, wherein a composite gate spacer including a confining portion on sidewalls of the source and drain contacts; and
an electrically insulating substrate isolation layer having a first thickness aligned to be between the gate all around structure, the gate spacer and the substrate and a second thickness present between the source and drain semiconductor contacts and the substrate, wherein a base portion of the gate spacer has an L-shaped geometry including a portion that warps over an upper surface of a portion of the electrically insulating substrate isolation layer having the first thickness.

16. The semiconductor device of claim 15, wherein the first thickness of the electrically insulating substrate isolation layer is greater than the second thickness.

17. The semiconductor device of claim 15, wherein the gate spacer is a composite gate spacer including a confining portion on sidewalls of the source and drain contacts, the composite gate spacer including confining portions on sidewalls of the source and drain contacts to epitaxial growth of the source and drain contact to provide source and drain sidewalls that are planar.

18. The semiconductor device of claim 15, wherein the composite gate spacer includes an inner gate spacer, a nanosheet stack spacer, and outer gate spacer, wherein a first material provides the nanosheet stack spacer including that at least the base portion of the gate spacer having the L-shaped geometry, a second material provides the inner gate spacer and a third material provides the outer gate spacer.

19. The semiconductor device of claim 18, wherein the second material that provides the inner gate spacer provides a material composition for the electrically insulating substrate isolation layer.

20. The semiconductor device of claim 15 further comprising an air gap between the source and drain contacts and a portion of the electrically insulating substrate isolation layer having the second thickness.
